(19) United States
(12) Patent Application Publication
(10) Pub. No.: US 2018/0254257 A1
(43) Pub. Date: Sep. 6, 2018

(54) PACKAGE STRUCTURE AND METHOD OF MANUFACTURING PACKAGE STRUCTURE

(71) Applicant: InnoLux Corporation, Miao-Li County (TW)

(72) Inventors: Yi-Hung Lin, Miao-Li County (TW); Li-Wei Sung, Miao-Li County (TW)

(21) Appl. No.: 15/889,216

(22) Filed: Feb. 6, 2018

Related U.S. Application Data
(60) Provisional application No. 62/467,254, filed on Mar. 6, 2017.

(30) Foreign Application Priority Data
Aug. 16, 2017 (CN) 201710702304.6

(51) Int. Cl. H01L 23/00; H01L 23/544; H01L 21/48; H01L 23/498

(52) U.S. Cl. CPC H01L 24/81; H01L 23/544; H01L 21/4853; H01L 22/14; H01L 23/49822; H01L 23/49838; H01L 2223/54426; H01L 21/4857

(57) ABSTRACT

A package structure includes a die, a first insulating layer and a first conductive layer. The die includes a first alignment pattern. The first insulating layer includes a first opening. The first conductive layer includes a first conductive pattern and a second alignment pattern. The first conductive pattern is located in the first opening and the second alignment pattern is located on the first insulating layer. The first alignment pattern and the second alignment pattern are disposed corresponding to each other.

### CROSS REFERENCE TO RELATED APPLICATION

This application claims the benefit of U.S. Provisional Application No. 62/467,254, which was filed on Mar. 6, 2017, and is incorporated herein by reference.

### BACKGROUND OF THE DISCLOSURE

### 1. Field of the Disclosure

The disclosure relates to a package structure and a method of manufacturing the package structure and, more particularly, to a package structure capable of improving the accuracy of alignment effectively and a method of manufacturing the package structure.

### 2. Description of the Prior Art

In flip chip package technology, solder bumps are formed on contact pads of a die, the die is reversed to align the solder bumps with circuits of a substrate, and the solder bumps are melted by a reflow process. After the solder bumps are cooled and solidified, the solder bumps become signal transmitting channels between the die and the substrate. Since the prior art utilizes the solder bumps on the contact pads of the die and the circuits of the substrate to perform alignment, the accuracy of alignment cannot be ensured. Furthermore, to measure overlay error after alignment, the prior art has to measure the overlay error in X and Y directions separately, such that the measurement efficiency decreases. Moreover, after bonding the die to the substrate, the prior art has to perform a molding process first and then measures whether the electrical property of the package structure is normal. The prior art cannot measure the electrical property of the package structure together with a conductive layer (e.g. redistribution layer, RDL) after bonding.

### SUMMARY OF THE DISCLOSURE

The disclosure provides a package structure capable of improving the accuracy of alignment effectively and a method of manufacturing the package structure, so as to solve the aforesaid problems.

According to an embodiment of the disclosure, a package structure comprises a die, a first insulating layer and a first conductive layer. The die comprises a first alignment pattern. The first insulating layer comprises a first opening. The first conductive layer comprises a first conductive pattern and a second alignment pattern. The first conductive pattern is located in the first opening and the second alignment pattern is located on the first insulating layer. The first alignment pattern and the second alignment pattern are disposed corresponding to each other.

According to an embodiment of the disclosure, a method of manufacturing a package structure comprises steps of forming a first insulating layer, wherein the first insulating layer comprises a first opening; forming a first conductive layer on the first insulating layer, wherein the first conductive layer comprises a first conductive pattern and a second alignment pattern, the first conductive pattern is filled into the first opening, and the second alignment pattern is formed on the first insulating layer and corresponds to a first alignment pattern formed on a die; aligning the die with the first conductive layer by the first alignment pattern and the second alignment pattern; and bonding the die to the first conductive layer.

As mentioned in the above, the disclosure disposes the alignment patterns on the die and the conductive layer, respectively, so the disclosure can utilize the alignment patterns to align the die with the conductive layer. After alignment, the alignment patterns on the die and the conductive layer overlap with each other. The disclosure can measure the overlay error in X and Y directions simultaneously according to the overlap between the alignment patterns on the die and the conductive layer, so as to improve the measurement efficiency. Furthermore, the disclosure may form a test pattern on the conductive layer while manufacturing the conductive layer. After bonding the die to the conductive layer, the disclosure can utilize the test pattern on the conductive layer to measure the electrical property of the die and the conductive layer directly. After confirming the electrical property is normal, the disclosure performs a molding process for the package structure, so as to improve the yield rate of the package structure.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a sectional view illustrating a package structure according to an embodiment of the disclosure.

FIG. 2 is a top view illustrating the package structure shown in FIG. 1.

FIG. 3A is another schematic view illustrating the first alignment pattern and the second alignment pattern.

FIG. 3B is another schematic view illustrating the first alignment pattern and the second alignment pattern.

FIG. 3C is another schematic view illustrating the first alignment pattern and the second alignment pattern.

FIG. 4A is a schematic view illustrating a test pattern corresponding to one contact pad.

FIG. 4B is another schematic view illustrating a test pattern corresponding to one contact pad.

FIG. 4C is another schematic view illustrating a test pattern corresponding to two contact pads.

FIG. 5 is a sectional view illustrating a package structure according to another embodiment of the disclosure.

FIGS. 6A to 6I are schematic views illustrating the processes of manufacturing the package structure shown in FIG. 1.

### DETAILED DESCRIPTION

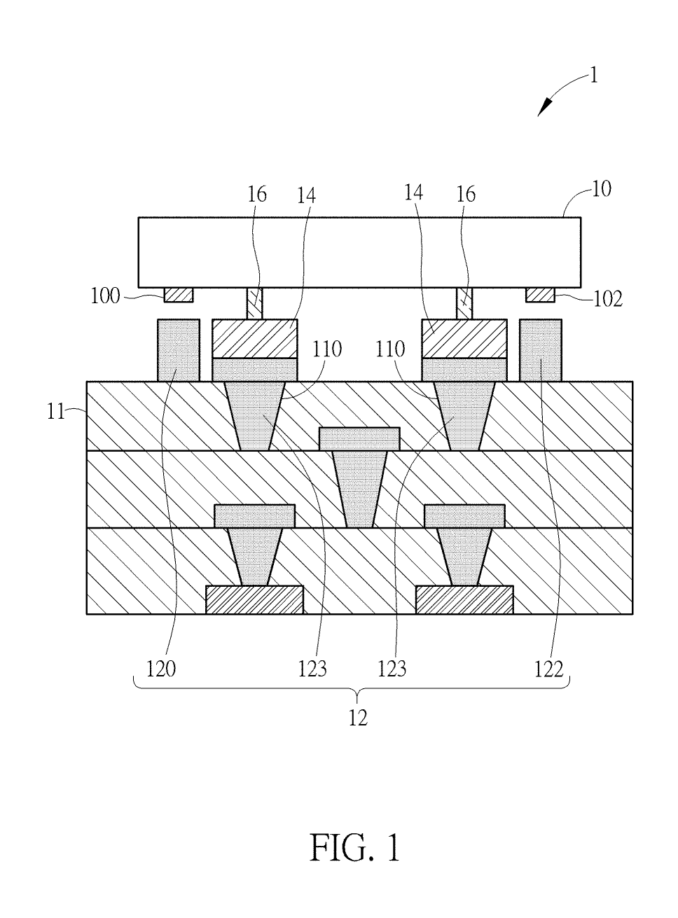

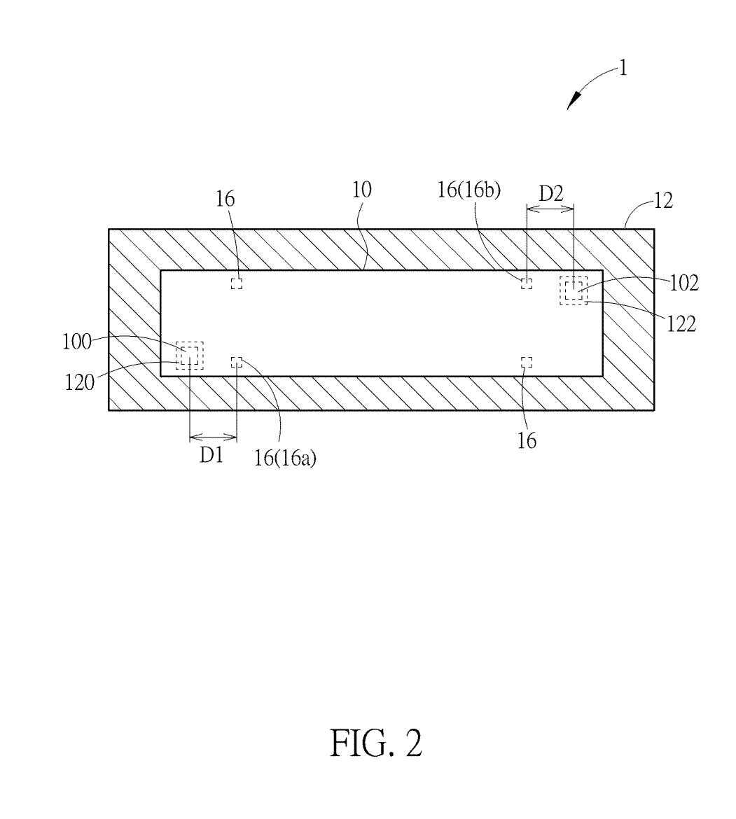

Referring to FIGS. 1 and 2, FIG. 1 is a sectional view illustrating a package structure 1 according to an embodiment of the disclosure and FIG. 2 is a top view illustrating the package structure 1 shown in FIG. 1.

As shown in FIGS. 1 and 2, the package structure 1 comprises a die 10, a first insulating layer 11, a first conductive layer 12, a plurality of conductive members 14 and a plurality of contact pads 16. The conductive members 14 are used for connecting the die 10 and the first conductive layer 12. In this embodiment, the conductive members 14 may be, but not limited to, solder bumps. Furthermore, the first conductive layer 12 may be a redistribution layer (RDL) on a circuit board. The die 10 comprises a first alignment pattern 100 and a third alignment pattern 102, and the first conductive layer 12 comprises a second alignment pattern 120 and a fourth alignment pattern 122, wherein the first alignment pattern 100 and the second alignment pattern 120 are disposed corresponding to each other, and the third alignment pattern 102 and the fourth alignment pattern 122 are disposed corresponding to each other. In this embodiment, the size of the first alignment pattern 100 is smaller than the size of the second alignment pattern 120, and the size of the third alignment pattern 102 is smaller than the size of the fourth alignment pattern 122. However, in another embodiment, the size of the first alignment pattern 100 may be larger than the size of the second alignment pattern 120, and the size of the third alignment pattern 102 may be larger than the size of the fourth alignment pattern 122. In other words, the sizes of the first alignment pattern 100, the second alignment pattern 120, the third alignment pattern 102 and the fourth alignment pattern 122 may be determined according to practical applications as long as the size of the first alignment pattern 100 is different from the size of the second alignment pattern 120, and the size of the third alignment pattern 102 is different from the size of the fourth alignment pattern 122. In this embodiment, a first contact pad 16a of the contact pads 16 is adjacent to the first alignment pattern 100 and a second contact pad 16b of the contact pads 16 is adjacent to the third alignment pattern 102.

The first insulating layer 11 comprises a first opening 110 and the first conductive layer 12 further comprises a first conductive pattern 123, wherein the first conductive pattern 123 is located in the first opening 110, and the second alignment pattern 120 and the fourth alignment pattern 122 are located on the first insulating layer 11. In this embodiment, the disclosure may form the first opening 110 on the first insulating layer 11 first and then fill the first conductive pattern 123 into the first opening 110.

In this embodiment, the package structure 1 may be manufactured by flip chip package technology. First of all, the disclosure may form the conductive members 14 on the contact pads 16 of the die 10 and then reverse the die 10 to align the die 10 with the first conductive layer 12. At this time, the disclosure can utilize the first alignment pattern 100, the second alignment pattern 120, the third alignment pattern 102 and the fourth alignment pattern 122 to align the die 10 with the first conductive layer 12. After alignment, the first alignment pattern 100 on the die 10 and the second alignment pattern 120 on the first conductive layer 12 overlap with each other, and the third alignment pattern 102 on the die 10 and the fourth alignment pattern 122 on the first conductive layer 12 overlap with each other. The disclosure can measure the overlay error in X and Y directions simultaneously according to the overlap between the alignment patterns on the die 10 and the first conductive layer 12, so as to improve the measurement efficiency.

After finishing alignment, the conductive members 14 may connect the contact pads 16 of the die 10 and the first conductive patterns 123 of the first conductive layer 12 by low-temperature ultrasound or anisotropic conductive film (ACF), so as to prevent thermal expansion from occurring in the die 10 and the first conductive layer 12 during high-temperature process and/or avoid reducing reliability.

In this embodiment, a distance D1 between the first alignment pattern 100 and the first contact pad 16a may be larger than or equal to 20 μm and smaller than or equal to 200 μm, such that a measurement equipment can well recognize the overlap between the first alignment pattern 100 and the second alignment pattern 120. Similarly, a distance D2 between the third alignment pattern 102 and the second contact pad 16b may be larger than or equal to 20 μm and smaller than or equal to 200 μm, such that the measurement equipment can well recognize the overlap between the third alignment pattern 102 and the fourth alignment pattern 122. It should be noted that the aforesaid distances D1, D2 may be measured by center-to-center or edge-to-edge.

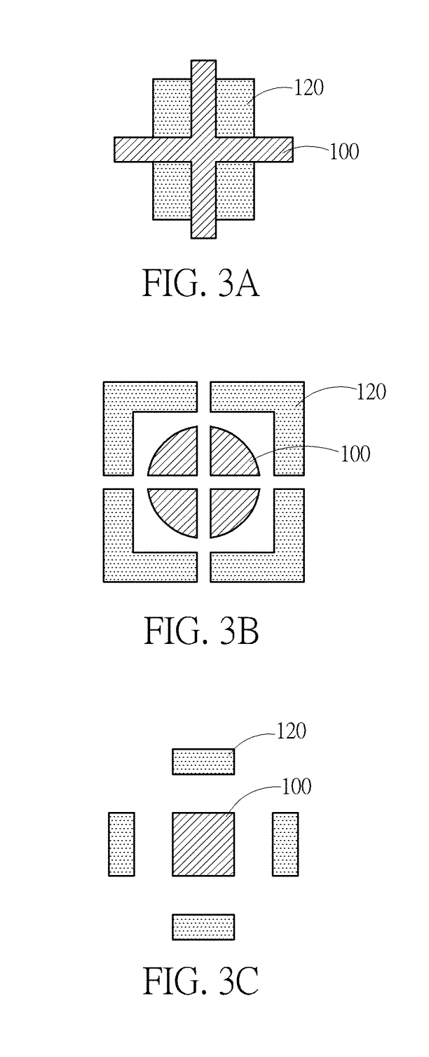

Referring to FIGS. 3A to 3C, FIG. 3A is another schematic view illustrating the first alignment pattern 100 and the second alignment pattern 120, FIG. 3B is another schematic view illustrating the first alignment pattern 100 and the second alignment pattern 120, and FIG. 3C is another schematic view illustrating the first alignment pattern 100 and the second alignment pattern 120.

As shown in FIGS. 3A to 3C, the shapes of the first alignment pattern 100 and the second alignment pattern 120 may be designed according to practical applications as long as the first alignment pattern 100 and the second alignment pattern 120 can overlap with each other in X and Y directions. It should be noted that the shapes of the first alignment pattern 100 and the second alignment pattern 120 may also be designed according to practical applications and it will not be depicted herein. Furthermore, the first alignment pattern 100 and the third alignment pattern 102 may be, but not limited to, sections extended from a circuit of the die 10, and the second alignment pattern 120 and the fourth alignment pattern 122 may be, but not limited to, sections extended from a circuit of the first conductive layer 12. It should be noted that if there is not enough space on the die 10, the disclosure may utilize the contact pads 16 on the die 10 to be the aforesaid first alignment pattern 100 and third alignment pattern 102.

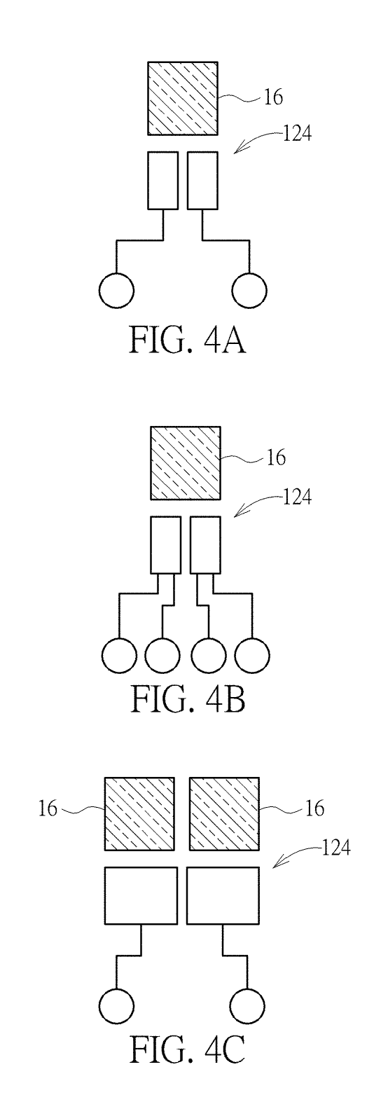

Referring to FIGS. 4A to 4C, FIG. 4A is a schematic view illustrating a test pattern 124 corresponding to one contact pad 16, FIG. 4B is another schematic view illustrating a test pattern 124 corresponding to one contact pad 16, and FIG. 4C is another schematic view illustrating a test pattern 124 corresponding to two contact pads 16.

In this embodiment, the aforesaid first conductive layer 12 may further comprise a test pattern 124 shown in FIGS. 4A to 4C. The disclosure may form the test pattern 124 on the first conductive layer 12 while manufacturing the first conductive layer 12. After bonding the die 10 to the first conductive layer 12, the contact pads 16 of the die 10 are electrically connected to the test pattern 124 of the first conductive layer 12 through the conductive members 14. As shown in FIG. 4A, the test pattern 124 is two-point type and electrically connected to one contact pad 16. As shown in FIG. 4B, the test pattern 124 is four-point type and electrically connected to one contact pad 16. Accordingly, the disclosure can utilize the test pattern 124 on the first conductive layer 12 to measure the electrical property (e.g. impedance) of the die 10 and the first conductive layer 12 directly. Still further, as shown in FIG. 4C, the test pattern 124 of the disclosure may be electrically connected to two contact pads 16, so as to test the electrical property (e.g. voltage, current, impedance, etc.) between the two contact pads 16. After confirming the electrical property is normal, the disclosure performs a molding process for the package structure 1, so as to improve the yield rate of the package structure 1.

In this embodiment, the contact pad 16 electrically connected to the test pattern 124 may be, but not limited to, the aforesaid first contact pad 16a. Furthermore, the test pattern 124 may be a section extended from a contact pad of the first conductive layer 12. In this embodiment, a line width of the test pattern 124 may be smaller than 20 μm and a line length of the test pattern 124 may be larger than 50 μm. Moreover, an area of the first contact pad 16a may be larger than or equal to 400 μm² and smaller than or equal to 10⁶ μm², and an area of the test pattern 124 may be larger than or equal to 400 μm² and smaller than or equal to 10⁶ μm².

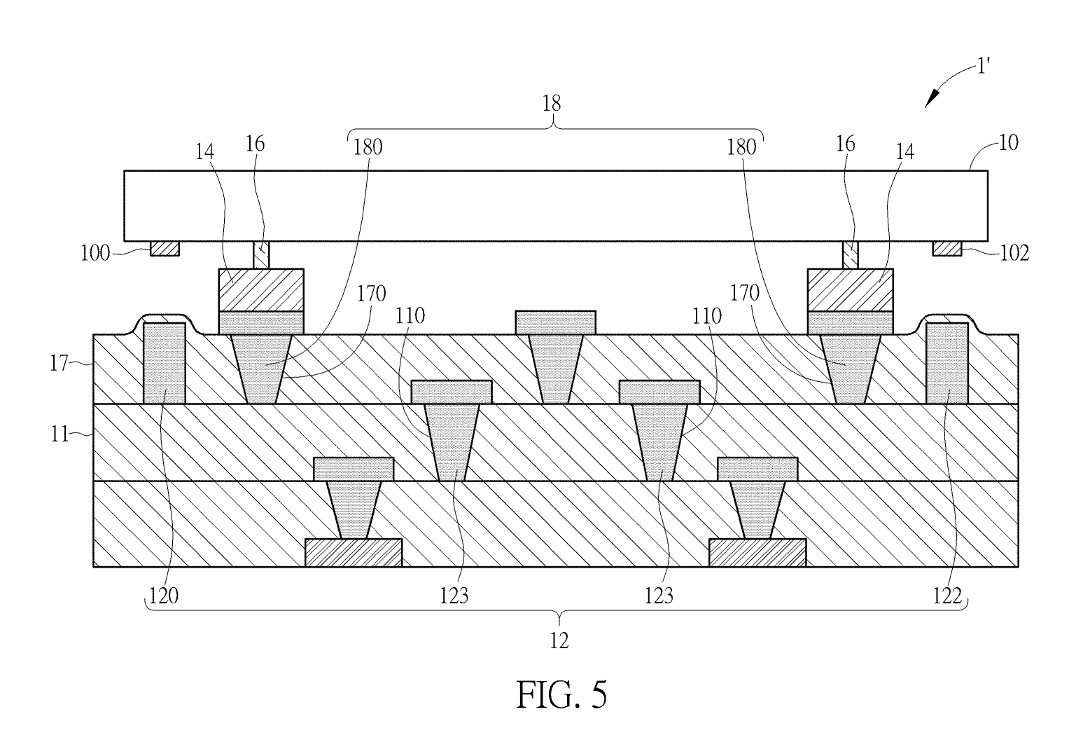

Referring to FIG. 5, FIG. 5 is a sectional view illustrating a package structure 1′ according to another embodiment of the disclosure. The main difference between the package structure 1′ and the aforesaid package structure 1 is that the package structure 1′ further comprises a second insulating layer 17 and a second conductive layer 18. As shown in FIG. 5, the second conductive layer 18 is located between the die 10 and the first conductive layer 12, and the conductive members 14 connect the die 10 and the second conductive layer 18. In other words, the die 10 is bonded to the second conductive layer 18 and the second alignment pattern 120 and the fourth alignment pattern 122 are located on the first conductive layer 12 below the second conductive layer 18. The second insulating layer 17 comprises a second opening 170 and the second conductive layer 18 comprises a second conductive pattern 180, wherein the second conductive pattern 180 is located in the second opening 170. In this embodiment, the disclosure may form the second opening 170 on the second insulating layer 17 first and then fill the second conductive pattern 180 into the second opening 170. In this embodiment, the conductive members 14 may connect the contact pads 16 of the die 10 and the second conductive patterns 180 of the second conductive layer 18 by low-temperature ultrasound or anisotropic conductive film (ACF), so as to prevent thermal expansion from occurring in the die 10 and the second conductive layer 18 during high-temperature process and/or avoid reducing reliability. Furthermore, the first conductive layer 12 and the second conductive layer 18 may be redistribution layers on a circuit board.

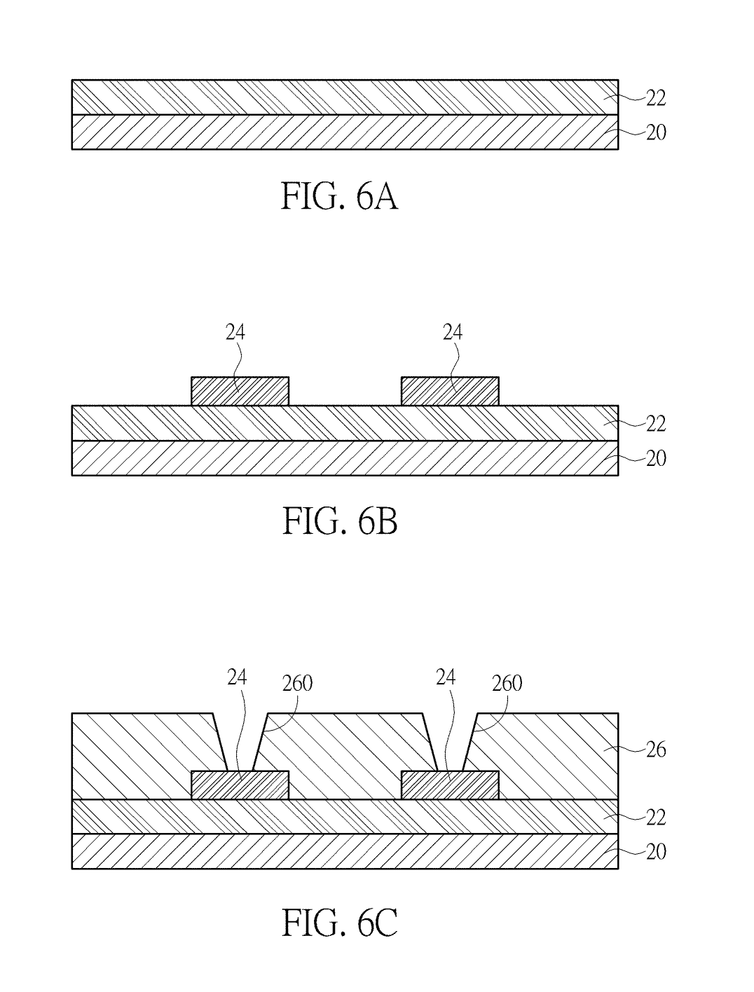

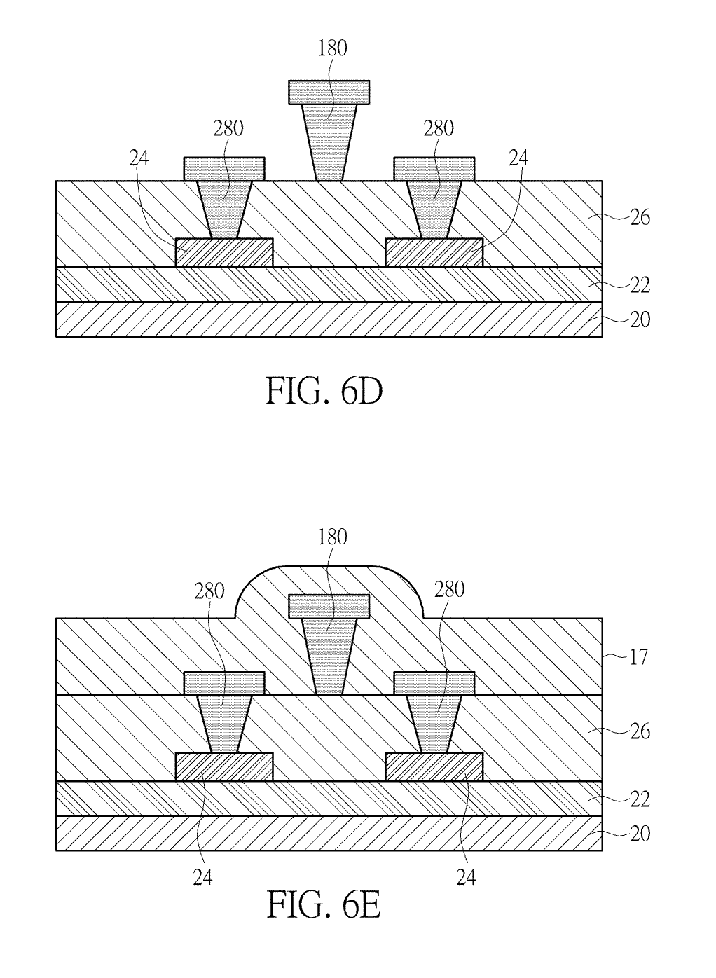

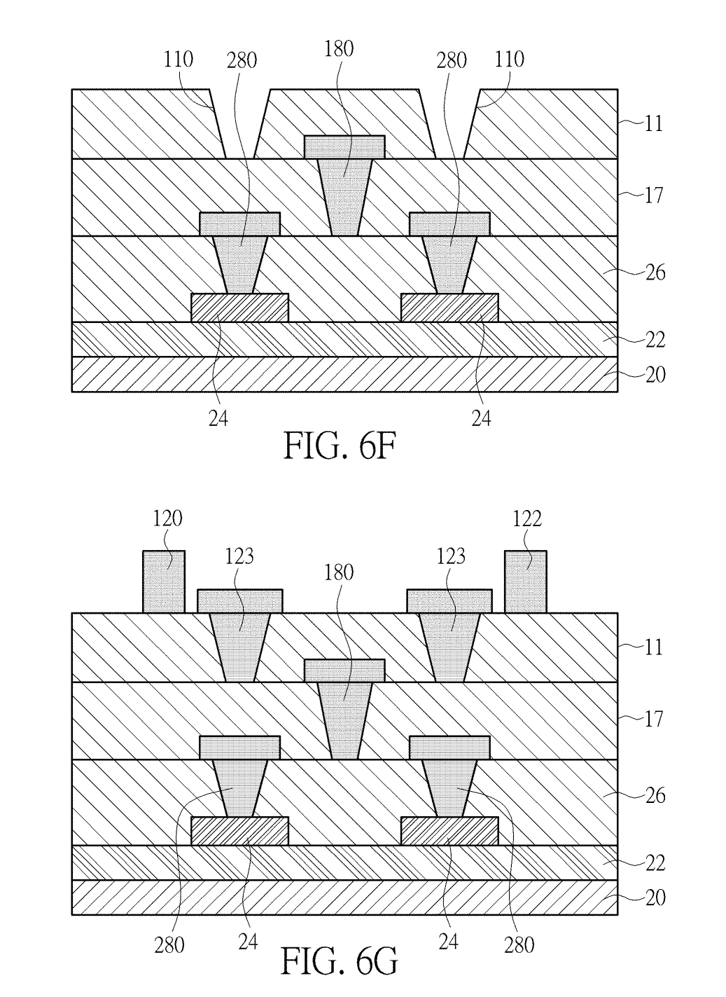

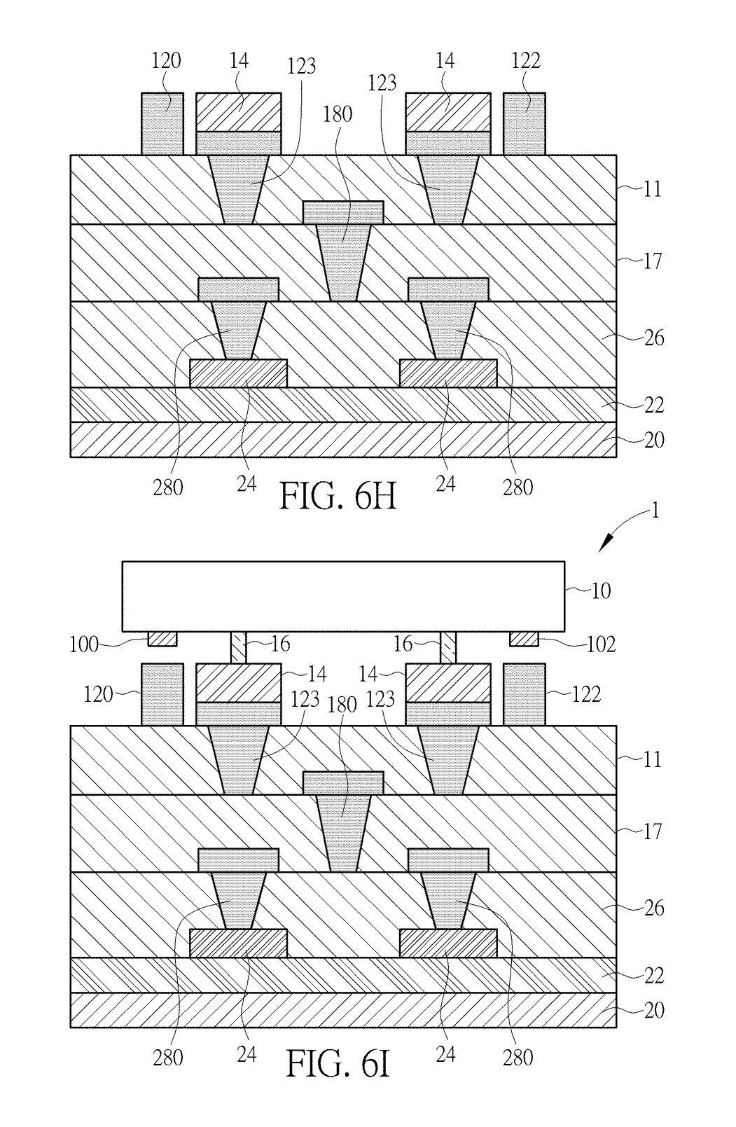

Referring to FIGS. 6A to 6I, FIGS. 6A to 6I are schematic views illustrating the processes of manufacturing the package structure 1 shown in FIG. 1. First of all, a release layer 22 is formed on a glass substrate 20, as shown in FIG. 6A. Then, a solder pad 24 is formed on the release layer 22, as shown in FIG. 6B. Then, a third insulating layer 26 is formed on the release layer 22 and a third opening 260 is formed on the third insulating layer 26, as shown in FIG. 6C. Then, a third conductive pattern 280 is filled into the third opening 260 and a second conductive pattern 180 is formed on the third insulating layer 26, as shown in FIG. 6D. Then, a second insulating layer 17 is formed on the third insulating layer 26, as shown in FIG. 6E. Then, a first insulating layer 11 is formed on the second insulating layer 17 and a first opening 110 is formed on the first insulating layer 11, as shown in FIG. 6F. Then, a first conductive pattern 123 is filled into the first opening 110 and the second alignment pattern 120 and the fourth alignment pattern 122 are formed on the first insulating layer 11, as shown in FIG. 6G. Then, a conductive member 14 is formed on the first conductive pattern 123, as shown in FIG. 6H. Then, the die 10 is aligned with the first conductive layer 12 by the first alignment pattern 100, the second alignment pattern 120, the third alignment pattern 102 and the fourth alignment pattern 122, so as to bond the die 10 to the first conductive layer 12. Accordingly, the processes of manufacturing the package structure 1 are finished.

As mentioned in the above, the disclosure disposes the alignment patterns on the die and the conductive layer, respectively, so the disclosure can utilize the alignment patterns to align the die with the conductive layer. After alignment, the alignment patterns on the die and the conductive layer overlap with each other. The disclosure can measure the overlay error in X and Y directions simultaneously according to the overlap between the alignment patterns on the die and the conductive layer, so as to improve the measurement efficiency. Furthermore, the disclosure may forma test pattern on the conductive layer while manufacturing the conductive layer. After bonding the die to the conductive layer, the disclosure can utilize the test pattern on the conductive layer to measure the electrical property of the die and the conductive layer directly. After confirming the electrical property is normal, the disclosure performs a molding process for the package structure, so as to improve the yield rate of the package structure.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A package structure comprising:
a die comprising a first alignment pattern;
a first insulating layer comprising a first opening; and
a first conductive layer comprising a first conductive pattern and a second alignment pattern, the first conductive pattern being located in the first opening, the second alignment pattern being located on the first insulating layer;
wherein the first alignment pattern and the second alignment pattern are disposed corresponding to each other.

2. The package structure of claim 1, wherein the die further comprises a third alignment pattern, the first conductive layer further comprises a fourth alignment pattern, the fourth alignment pattern is located on the first insulating layer, and the third alignment pattern and the fourth alignment pattern are disposed corresponding to each other.

3. The package structure of claim 1, further comprising a conductive member, the conductive member connecting the die and the first conductive layer.

4. The package structure of claim 3, wherein the conductive member connects the die and the first conductive layer by low-temperature ultrasound or anisotropic conductive film.

5. The package structure of claim 1, further comprising a conductive member and a second conductive layer, the second conductive layer being located between the die and the first conductive layer, the conductive member connecting the die and the second conductive layer.

6. The package structure of claim 5, wherein the conductive member connects the die and the second conductive layer by low-temperature ultrasound or anisotropic conductive film.

7. The package structure of claim 1, wherein the die further comprises a first contact pad, the first contact pad is adjacent to the first alignment pattern, and a distance between the first alignment pattern and the first contact pad is larger than or equal to 20 μm and smaller than or equal to 200 μm.

8. The package structure of claim 7, wherein an area of the first contact pad is larger than or equal to 400 μm² and smaller than or equal to 10⁶ μm².

9. The package structure of claim 1, wherein the first conductive layer further comprises a test pattern and an area of the test pattern is larger than or equal to 400 μm² and smaller than or equal to 10⁶ μm².

10. The package structure of claim 1, wherein the die further comprises a first contact pad, the first conductive layer further comprises a test pattern, and the first contact pad is electrically connected to the test pattern.

11. A method of manufacturing a package structure comprising steps of:
forming a first insulating layer, wherein the first insulating layer comprises a first opening;
forming a first conductive layer on the first insulating layer, wherein the first conductive layer comprises a first conductive pattern and a second alignment pattern, the first conductive pattern is filled into the first opening, and the second alignment pattern is formed on the first insulating layer and corresponds to a first alignment pattern formed on a die;
aligning the die with the first conductive layer by the first alignment pattern and the second alignment pattern; and
bonding the die to the first conductive layer.

12. The method of claim 11, wherein the die further comprises a third alignment pattern, the first conductive layer further comprises a fourth alignment pattern, the fourth alignment pattern is formed on the first insulating layer, and the method further comprising step of:
aligning the die with the first conductive layer by the first alignment pattern, the second alignment pattern, the third alignment pattern and the fourth alignment pattern.

13. The method of claim 11, further comprising step of:
forming a conductive member on the first conductive pattern; and
connecting the die and the first conductive layer by the conductive member.

14. The method of claim 13, further comprising step of:
connecting the die and the first conductive layer by low-temperature ultrasound or anisotropic conductive film.

15. The method of claim 11, wherein the die further comprises a first contact pad, the first contact pad is adjacent to the first alignment pattern, and a distance between the first alignment pattern and the first contact pad is larger than or equal to 20 μm and smaller than or equal to 200 μm.

16. The method of claim 15, wherein an area of the first contact pad is larger than or equal to 400 μm² and smaller than or equal to 10⁶ μm².

17. The method of claim 11, wherein the first conductive layer further comprises a test pattern and an area of the test pattern is larger than or equal to 400 μm² and smaller than or equal to 10⁶ μm².

18. The method of claim 11, wherein the die further comprises a first contact pad, the first conductive layer further comprises a test pattern, and the first contact pad is electrically connected to the test pattern.
